(19) United States
(12) Patent Application Publication
(10) Pub. No.: US 2005/0139848 A1
(43) Pub. Date: Jun. 30, 2005

(54) Image sensor package and method for manufacturing the same

(76) Inventor: Kuo-Chung Yee, Taipei (TW)

Correspondence Address: J C PATENTS, INC., 4 VENTURE, SUITE 250, IRVINE, CA, 92618, US

(21) Appl. No.: 11/028,150

(22) Filed: Dec. 30, 2004

(30) Foreign Application Priority Data
Dec. 31, 2003 (TW) 92137701

(51) Int. Cl. H01L 31/0203

(52) U.S. Cl. 257/98

(57) ABSTRACT

An image sensor package includes a substrate, a chip, a transparent cover, and a lens module. The substrate has an upper surface and a lower surface, and has a plurality of connection pads disposed on the lower surface and a though opening. The chip has an active surface, and has an image sensor disposed on the active surface, corresponding to the through opening of the substrate. Also and, a plurality of bumps are disposed at peripheral region of the active surface and are electrically connected to the pads. The transparent cover is disposed in the through opening of the substrate and covers the image sensor. The lens module is disposed on the upper surface for transmitting light to the image sensor.

### CROSS-REFERENCE TO RELATED APPLICATION

This application claims the priority benefit of Taiwan application serial no. 92137701, filed on Dec. 31, 2003.

### BACKGROUND OF THE INVENTION

1. Field of Invention

The present invention relates to structure of image sensor package. More particularly, the present invention relates to structure of image sensor package having a reduced height in whole structure.

2. Description of Related Art

The image sensor semiconductor is a semiconductor chip, in which the optical signals are converted into electric signals. The image sensor semiconductor includes an optical sensing device, such as a complementary metal-oxide semiconductor (CMOS) device or a charge coupled device (CCD).

Taking the U.S. Pat. No. 5,636,104 as a reference of the invention, it discloses a structure of image sensor package 10, as shown in FIG. 1. The structure of image sensor package 10 includes a chip 30, a housing 14, a lens 16, a glass 18, and a substrate 20. The chip 30 is electrically coupled on the substrate 20, using the technology of bonding connection. The chip 30 has an optical sensing device 32, located within the housing 14. The housing 14 adheres to the substrate 20, and supports the lens 16 and the glass 18. The housing 14, the glass 18, the substrate 20 form a close space 12, so as to adapt the chip 30. When the light passes the lens 16 and the glass 18 and reaches to the optical sensing device 32, the optical sensing device 32 reacts with the light and converts the light into electric signals. The substrate 20 is disposed with multiple metal circuit lines 22, multiple bonding pads 24, and multiple solder balls 26. The solder balls 26 are electrically coupled to the chip 30 through the metal circuit lines 22 and the bonding pads 24, and further electrically coupled to an external circuit (not shown), so as to transmit the signals from the optical sensing device 32.

The conventional structure of image sensor package 10 is restricted to the manner of using the bonding technology for mounting the chip 30 to the substrate 20. Since the total height, which is a distance between the lens and the substrate, is too large, it restricts the adjustment on the focal distance. Moreover, when the conventional structure of image sensor package 10 is disposed on an electronic apparatus, the volume of the electronic apparatus becomes large due to the total height of the structure of image sensor package 10 being over long.

Referring to FIG. 2, another conventional structure of image sensor package mainly includes a chip 80, a housing 64, a lens 66, a glass 68, and a resin layer 70. The chip 80 is electrically coupled to the resin layer 70 by a flip-chip technology. The chip 80 has an optical sensing device 82 and multiple bumps 84. The housing 64 adheres to the resin layer 70 and supports the lens 66. The glass 68 is disposed between the housing 64 and the resin layer 70. The resin layer 70 has multiple metal circuit lines 72 and multiple connection ends 76. The metal circuit lines 72 are used to electrically connect the connection ends 76 to the bumps 84 of the chip 80. The connection ends 76 is electrically coupled to an external circuit 90, so as to transmit the signals of the optical sensing device 82. Even though the total height of the foregoing structure of the image sensor package, which is the distance from the lens 66 to the chip 80, has been reduced, the total height of the structure of the image sensor package 60 is still over long, with respect to a small electronic products.

Therefore, it is necessary to provide a structure of image sensor package at a wafer level, so as to solve the foregoing disadvantages.

### SUMMARY OF THE INVENTION

The invention provides a structure of image sensor package, having a reduced package height.

For achieving the foregoing objective, the invention provides a structure of image sensor package, including a substrate, a chip, a transparent cover, and a lens module. The substrate has an upper surface and a lower surface, multiple connection pads disposed on the lower surface, and a through hole. The chip has an active surface, an optical sensing device disposed on the active surface, and multiple bumps disposed on the active surface at the peripheral regions with electrical coupling to the connection pads. The transparent cover is disposed in the through hole of the substrate and covers over the optical sensing device. The lens module is disposed on the upper surface of the substrate.

According to the structure of the image sensor package in the invention, the chip is coupled to the substrate by a flip-chip type, so that the structure height of the image sensor package can be reduced. Moreover, the transparent cover directly covers over the chip, so that the structure height of the image sensor package can also be reduced. As a result, in comparing with the conventional structure of image sensor package, the novel structure of image sensor package has the smaller structure height.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view, schematically illustrating a conventional structure of an image sensor package.

FIG. 2 is a cross-sectional view, schematically illustrating another conventional structure of an image sensor package.

FIG. 3 is a cross-sectional view, schematically illustrating a structure of an image sensor package, according to embodiment of the invention.

FIGS. 4-14 are drawings, schematically illustrating the fabrication processes for the image sensor package, according to embodiment of the invention.

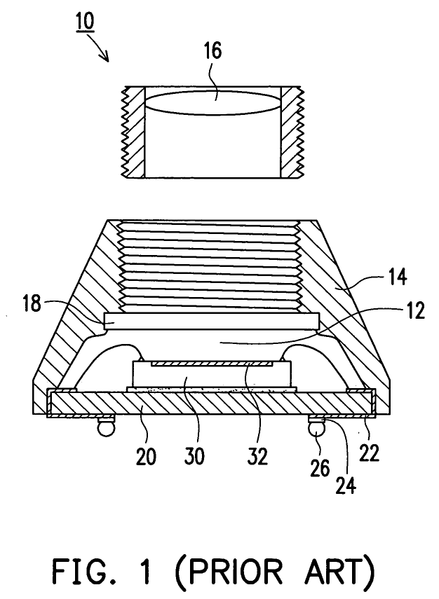

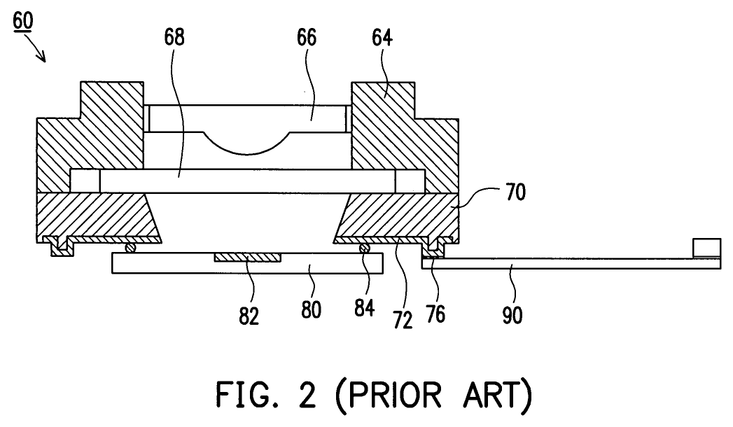

### DESCRIPTION OF THE PREFERRED EMBODIMENTS

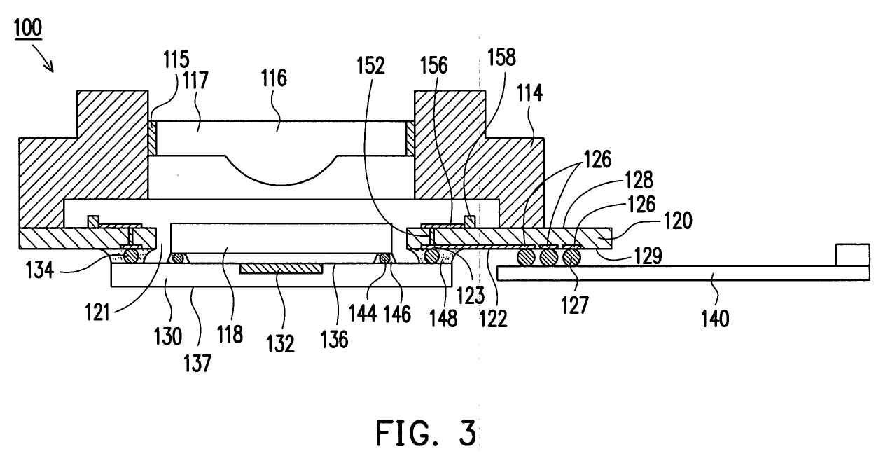

Referring to FIG. 3, it is a cross-sectional view, schematically illustrating a structure of an image sensor package 100, according to embodiment of the invention. The structure of an image sensor package 100 includes a chip 130, a transparent cover 118, a substrate 120, and a lens module 116. The chip 130 has an active surface 136, a back surface 137, an optical sensing device 132, and multiple bumps 134 disposed on the active surface 136. The bumps 134 are located at the peripheral region of the active surface on the chip 130. In detail, the bumps 134 can be disposed on one side, two sides, three sides, or four sides of the active surface 136. The optical sensing device 132 can be a Complementary Metal-Oxide Semiconductor (CMOS) device or a charge coupled device (CCD). The bumps 134 can be a gold bump or a solder bump.

The transparent cover 118 is adhered to the chip 130 by a sealant 146 and covers the optical sensing device 132. The sealant 146 can be an UV adhesive, and preferably, several spacing particles 144 are mixed therein. The sealant 146 is disposed between the transparent cover 118 and the chip 130, and a distance between them is determined by the size of the spacing particles 144. The transparent cover 118 can be an optical filter, such as an infrared low pass filter, or is formed from transparent material, such as glass. The spacing particles 144 can be formed by, for example, borosilicate glasses.

The substrate 120 has an upper surface 128 and a lower surface 129 against to each other, and a through hole 121 penetrating through the substrate 120 and corresponding to the optical sensing device 132 of the chip 130. The bumps 134 of the chip 130 are connected to the connection pads 123 on the lower surface 129 of the substrate 120 by the flip-chip technology, and the transparent cover 118 is located within the through hole 121. An underfill 148 is disposed between the chip 130 and the lower surface 129 of the substrate 120, and encapsulating the bumps 134. The connection pads 126 are disposed on the lower surface 129 of the substrate 120, and are electrically connected to the bumps 134 of the chip 130 via multiple first metal circuit lines 122 and connections pads 123. The connection pad 126 can be electrically connected to an external circuit 140, such as a flexible printed circuit, by multiple solder balls 127, which are processed by thermal pressing process. The ordinary skilled artisans can know that the substrate 120 can also have a solder mask layer (not shown), disposed on the lower surface 129, so as to define the connection pad 123 and connection pad 126. The substrate 120 is formed by material of Fiber Glass Reinforced Epoxy Resin, such as FR4 Fiber Glass Reinforced Epoxy Resin substrate or Fiber Glass Reinforced Bismalemide Triazine (BT) resin substrate.

The substrate 120 is a multi-layer substrate. In addition, multiple second circuit lines 156 are disposed on the upper surface 128 of the substrate 120, and multiple electrical vias 152 for electrically connecting the first circuit lines 122 and the second circuit lines 156. Multiple electronic devices 158, such as passive devices, are disposed on the upper surface 128 of the substrate 120, and are electrically connected to the second metal circuit lines 156. The electrical via 152 can be a laser via.

The lens module 116 has a lens 117, which is supported on the upper surface 128 of the substrate 120 by a housing 114, so as to focus the light onto the optical sensing device 132. The housing 114 is adhered to the upper surface 128 of the substrate 120. The lens module 116 additionally includes an adjusting device 115, used to adjust a distance between the lens 117 and the optical sensing device 132.

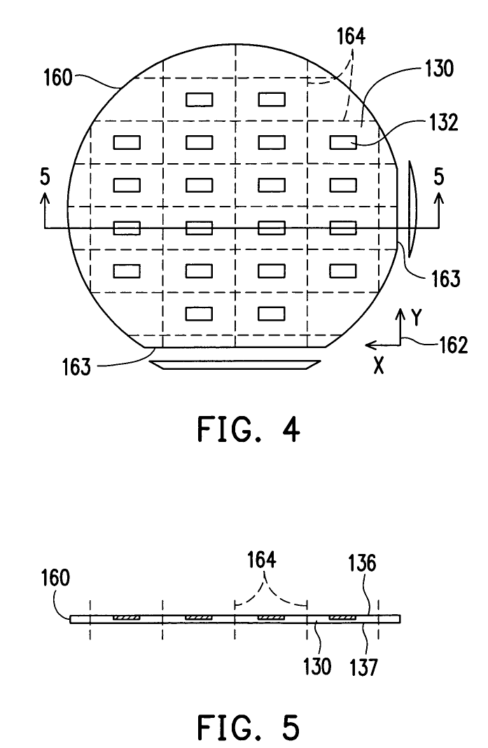

Referring to FIGS. 4-14, they are the drawings, schematically illustrating the method for fabricating the structure of image sensor package 100, according to the present invention.

In FIGS. 4 and 5, a wafer 160 has multiple chips 130, and the chips 130 are separated by the cutting line 164. The wafer 160 or the chips 130 has an active surface 136 and a back surface 137. Each the chip 130 has an optical sensing device 132, disposed on the active surface 136. The cutting line 164 is located on the active surface 136 of the wafer 160 or the chip 130.

At first, a set of alignment mark, such as two cutting openings 163, is formed on the wafer 160 by cutting, so as to define a two-dimensional coordinate 162. By this two-dimensional coordinate 162, and also referencing to the length and the width of the chip 130, the cutting line can be defined on the back surface 137 of the wafer 160, and the wafer 160 can be precisely cut. It should be noted that, in the subsequent fabrication processes of the method of the invention, the wafer 160 is cut along the cutting line 164 for cutting-out the singulated chip 130. However, in preferred situation, the wafer 160 is cut on the back surface 137 of the wafer 160, but the back surface 137 has no cutting line. In this situation, the wafer 160 should provide an alignment mark, so as to be able to cut the wafer 160 from the back surface 137. The alignment mark can be any type of opening, such as a cutting hole, through hole, or groove, which are used to define the cutting coordinate or cutting line on the back surface 137 of the wafer 160.

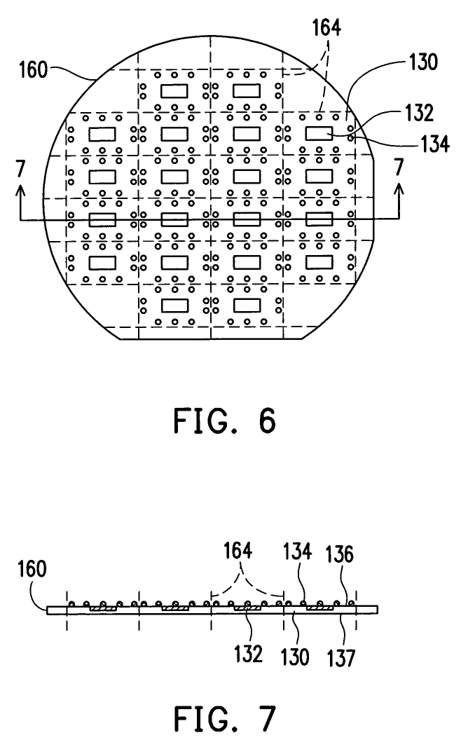

Referring to FIG. 6 and FIG. 7, multiple bumps 134 are formed on the active surface 136 of the chip 130, and are disposed at the periphery of the active surface 136.

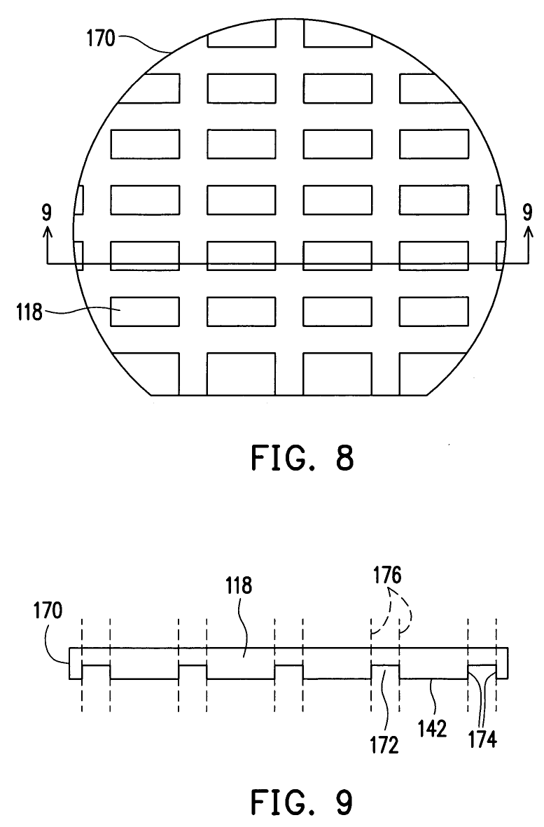

Referring to FIGS. 8 and 9, a transparent cover substrate 170 is first provided. A plurality of grooves 172 in longitudinal and transversal directions are formed a surface 142 of the transparent cover substrate 170. Both sides 174 of each groove 172 respectively define the two cutting lines 176, and also define multiple cover 118 by this way.

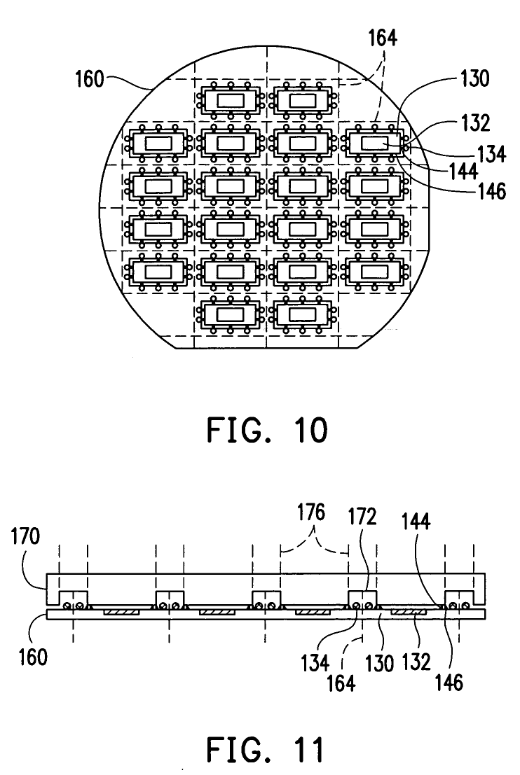

Referring to FIG. 10, it preferably includes multiple sealant 146. Each sealant is mixed with multiple spacers 144, and is disposed on the active surface 136 of the chips 130 in surrounding manner, and respectively surrounding the optical sensing device 132. The one ordinary skill in the art can understand that the sealant 146, mixed with the spacers 144, can be disposed the surface 142 of the transparent cover substrate 170.

Referring to FIG. 11, the transparent cover substrate 170 is aligned and covers over the wafer 160. The grooves 172 are respectively corresponding to the cutting lines 164 and the grooves 172 adapt the bumps 134. After then, the sealant 146 is cured, so that the transparent cover substrate 170 is adhered to the wafer 160. In this situation, the optical sensing device 132 is encapsulated in the sealant 146 and the transparent cover substrate 170.

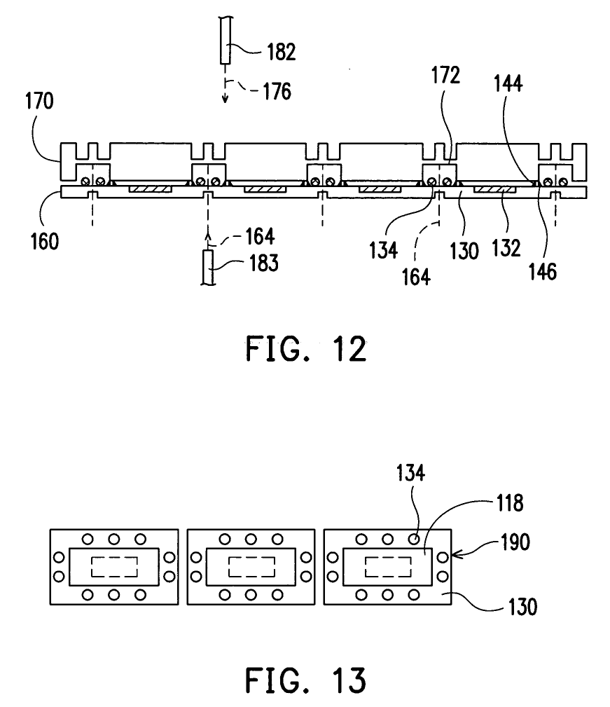

Referring to FIG. 12, by the 2-dimensional reference coordinate and referencing to the length and width of the chip 130, a cutting tool 183 cuts the wafer 160 from the back surface 137 of the wafer 160. Another cutting tool 182 is cutting the transparent cover substrate along the cutting line 176. In practical operation, the cutting tool 183 and 182 can be not completely cutting through the wafer 160 and the transparent substrate 170. And then, a braking process is subsequently performed, so as to form the singulated structure of optical device package 190, as shown in FIG. 13.

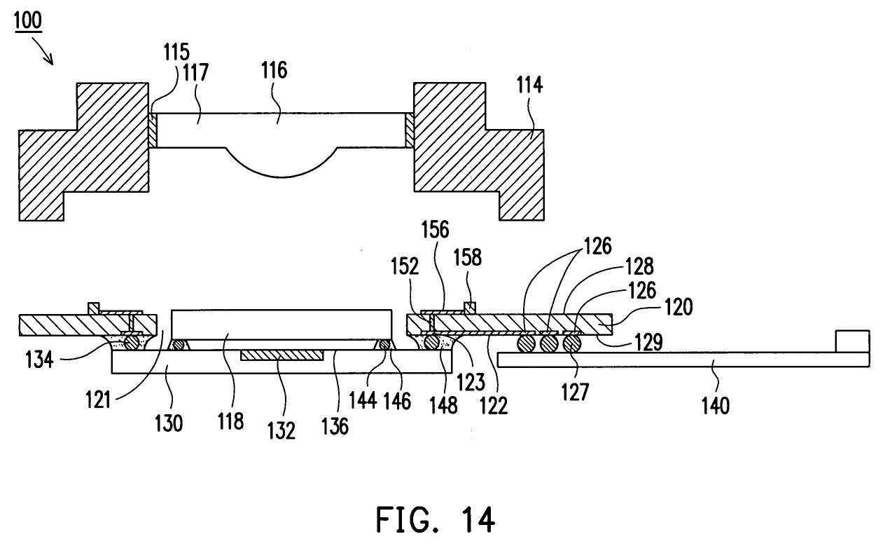

Referring to FIG. 14, a substrate 120 with an upper surface and a lower surface 129 has a through opening 121, multiple first metal circuit lines 122 disposed on the lower surface 129, multiple second metal circuit lines 156 disposed on the upper surface 128, and multiple conductive vias 152 for electrically connecting the second circuit lines 165 to the first circuit lines 122. The substrate 120 can additionally provide multiple electronic devices 158. For example, the electronic device 158 is disposed on the upper surface 128 and is connected to the second metal circuit lines 156.

The substrate 120 further has multiple connection pads 123 and 126, disposed on the lower surface 129, electrically connected to the first metal circuit line 122. The structure of optical device package 190 is affixed to the lower surface 129 of the substrate 120 by a flip-chip technology, in which the transparent cover 118 is located within the through opening 121. The bumps 134 of the chip 130 can be connected to the connection pads 123 by a reflow process. Then, an underfill 148 is dispensed with capillary effect, so as to fill between the chip 130 and the 120. The connection pads 126 can be electrically connected to an external circuit 140, such as the flexible printed circuit, by the solder balls 127 with a thermal pressing process. The ordinary skilled artisans can understand that the external circuit 140 can be any type of circuit board, and substrate 120 can be affixed to the external circuit board 140 by various methods.

After then, the lens module 116 with the housing 114 and the adjusting device 115 is adhered to the upper surface 128 of the substrate 120, so that the structure of image sensor package 100 can be formed, as shown in FIG. 3.

According to the embodiment of the invention, the4 chip 130 of the structure of image sensor package 100 is connected to the substrate 120 by the flip-chip type, so that a height of the structure of image sensor package 100 can be reduced, in which the height is a distance from the lens 117 to the chip 130. Moreover, the transparent cover 118 is directly covering over the chip 130, and can further reduce the height of the structure of image sensor package 100. As a result, comparing with the conventional structure of image sensor package, the structure of image sensor package 100 has a smaller total height.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A structure of image sensor package, comprising:
a substrate, having an upper surface and a lower surface, and a plurality of first connection pads disposed on the lower surface, and a through hole;
a chip, having an active surface, an optical sensing device disposed on the active surface, and a plurality of bumps disposed at a periphery of the active surface with electric connection to the first connection pads;
a transparent cover, disposed within the through hole of the substrate, and covering the optical sensing device; and
a lens module, disposed on the upper surface of the substrate.

2. The structure of image sensor package of claim 1, further comprising:
a sealant, disposed between the transparent cover and the chip, so as to adhere the transparent cover to the chip.

3. The structure of image sensor package of claim 2, further comprising:
a plurality of spacers, disposed in the sealant, so as to control a distance between the transparent cover and the chip.

4. The structure of image sensor package of claim 1, further comprising:
an underfill, disposed between the chip and the substrate, and encapsulating the bumps.

5. The structure of image sensor package of claim 1, wherein the substrate further comprises:
a plurality of second connection pads, disposed on the lower surface of the substrate, electrically connecting to the first connection pads for further connecting to an external circuit.

6. The structure of image sensor package of claim 5, wherein the substrate further comprises a plurality of solder balls, used to electrically connect the second connection pads to the external circuit.

7. The structure of image sensor package of claim 1, wherein the lens module comprises:
a lens; and
a housing, supporting the lens, and adhering on the upper surface of the substrate.

8. The structure of image sensor package of claim 7, wherein the lens module farther comprises:
an adjusting device, used to adjust a distance between the lens and the optical sensing device.

9. The structure of image sensor package of claim 1, wherein the transparent cover is an optical filtering plate.

10. The structure of image sensor package of claim 1, wherein the optical sensing device is a Complementary Metal-Oxide Semiconductor (CMOS) device or a charge coupled device (CCD).

11. A method for forming a structure of image sensor package, comprising:
providing a wafer, having an active surface and a back surface, the active surface having a plurality of first cutting lines to define each chip, the chip having an optical sensing device disposed on the active surface;
forming a plurality of bumps on the active surface of the chip;
providing a transparent cover substrate, having a surface;
forming a plurality of grooves on the surface of the transparent cover substrate, wherein both sides of each of the grooves respectively define two second cutting lines, so as to define a plurality of transparent covers;
aligning and disposing the transparent cover substrate to wafer;
cutting the wafer from the back surface of the wafer and along the first cutting lines, and cutting the transparent cover substrate along the second cutting lines, so as to form a package structure of optical device in a singulated unit;
providing a substrate, having an upper surface and a lower surface, and having a plurality of first connection pads disposed on the lower surface, and having a through opening;
aligning the package structure of optical device with the substrate, so that the transparent cover is located within the through opening, and the bumps on the chip are disposed on the connection pads with electric connection; and
providing a lens module, adhering to the upper surface of the substrate, so as to form the structure of image sensor package.

12. The method in claim 11, further comprising:
forming a set of alignment marks on the wafer, for allowing the wafer to be cut from the back surface.

13. The method in claim 11, further comprising:
disposing a sealant on one of the transparent cover substrate and the chip, so that the transparent cover substrate is adhered on the chip.

14. The method in claim 13, further comprising:
providing a plurality of spacers mixed into the sealant, so as to control a distance between the transparent cover substrate and the chip.

15. The method in claim 11, further comprising:
providing an underfill, disposed between the chip and the substrate, and encapsulating the bumps.

16. The method in claim 11, wherein the substrate comprises a plurality of second connection pads, disposed on the lower surface of the substrate, electrically connecting to the first connection pads for further connecting to an external circuit, and the method further comprises:
disposing a plurality of solder balls on the second connection pads; and
electrically connecting the solder balls to the external circuit.

17. The method in claim 16, wherein the method further comprises:
disposing a plurality of electronic devices onto the upper surface of the substrate and further electrically connecting to the first connection pads.

18. The method in claim 11, wherein the step of providing the lens module comprises:
providing a lens; and
proving a housing, for supporting the lens, and adhering on the upper surface of the substrate.

19. The structure of image sensor package of claim 18, wherein the step of providing the lens module further comprises:
providing an adjusting device, used to adjust a distance between the lens and the optical sensing device.

20. A structure of optical device package, comprising:
a chip, having an active surface, an optical sensing device disposed on the active surface, and a plurality of bumps disposed at a periphery of the active surface; and
a transparent cover, covering over the optical sensing device.

21. The structure of optical device package of claim 20, further comprising:
a sealant, disposed between the transparent cover and the chip, so as to adhere the transparent cover to the chip; and
a plurality of spacers, disposed in the sealant, so as to control a distance between the transparent cover and the chip.

22. A method for forming a structure of optical device package, comprising:
providing a wafer, having an active surface and a back surface, the active surface having a plurality of first cutting lines to define each chip, the chip having an optical sensing device disposed on the active surface;
forming a plurality of bumps on the active surface of the chip;
providing a transparent cover substrate, having a surface;
forming a plurality of grooves on the surface of the transparent cover substrate, wherein both sides of each of the grooves respectively define two second cutting lines, so as to define a plurality of transparent covers;
aligning and disposing the transparent cover substrate to wafer; and
cutting the wafer from the back surface of the wafer and along the first cutting lines, and cutting the transparent cover substrate along the second cutting lines, so as to form the structure of optical device package in a singulated unit.

23. The method of claim 22, further comprising:
forming a set of alignment marks on the wafer, for allowing the wafer to be cut from the back surface.

24. The method in claim 22, further comprising:
disposing a sealant on one of the transparent cover substrate and the chip, so that the transparent cover substrate is adhered on the chip; and
providing a plurality of spacers mixed into the sealant, so as to control a distance between the transparent cover substrate and the chip.
